(19) United States
(12) Patent Application Publication
(10) Pub. No.: US 2026/0026038 A1
(43) Pub. Date: Jan. 22, 2026

(54) ISOLATION OF EPITAXIAL SOURCE/DRAIN REGIONS

(71) Applicant: International Business Machines Corporation, Armonk, NY (US)

(72) Inventors: HUIMEI ZHOU, Albany, NY (US); Jun Liu, Clifton Park, NY (US); Min Gyu Sung, Latham, NY (US); Rishikesh Krishnan, Cohoes, NY (US); Kai Zhao, Albany, NY (US); Dechao Guo, Short Hills, NJ (US)

(21) Appl. No.: 18/774,541

(22) Filed: Jul. 16, 2024

(51) Int. Cl. H01L 29/786; H01L 21/764; H01L 29/06; H01L 29/423; H01L 29/66; H01L 29/775

(52) U.S. Cl. CPC H10D 30/6713; H01L 21/764; H10D 30/014; H10D 30/43; H10D 30/6735; H10D 30/6757; H10D 62/121; H10D 64/017; H10D 64/018

(57) ABSTRACT

Embodiments of present invention provide a method of forming a semiconductor structure. The method includes forming a first and a second raw stack of nanosheets on a substrate; forming a sacrificial gate surrounding the first and second raw stacks of nanosheets; forming a sidewall spacer at a sidewall of the sacrificial gate; forming a buffer layer at sidewalls of the first and second raw stacks of nanosheets; forming an isolation layer between the buffer layers at the sidewalls of the first and second raw stacks of nanosheets; removing the buffer layer and the first and second raw stacks of nanosheets to create a first and a second opening; and forming a first and a second source/drain region in the first and second openings. A structure formed thereby is also provided.

### BACKGROUND

The present application relates to manufacturing of semiconductor integrated circuits. More particularly, it relates to method of forming isolation of epitaxial source/drain regions and the structure formed thereby.

A semiconductor system derives its basic functions from various semiconductor devices that the system contains. Various semiconductor devices are built from a fundamental building block that is knows as a complementary metal-oxide semiconductor field-effect-transistor (CMOS-FET), or commonly known as a transistor. There are various types of transistors such as, for example, planar transistors, fin-type transistors (FinFET), nanosheet (NS) transistors, vertical transistors, and gate-all-around (GAA) transistors, to list a few. A semiconductor chip may contain many such as thousands of transistors that are formed on a semiconductor substrate.

In a current process of forming transistors such as nanosheet transistors, there is a processing step, commonly known as a epi-cut step, that separates otherwise a merged epitaxial source/drain area into individual source/drain regions of individual transistors. However, the epi-cut step will expose portions of a sidewall spacer at the sidewall of the gate, and the exposed sidewall spacer may inevitably be subject to further erosion in subsequent processing steps and causing reliability issue.

### SUMMARY

Embodiments of present invention provide a semiconductor structure. The semiconductor structure includes a first and a second set of channel sheets on top of a semiconductor substrate; a metal gate surrounding the first and the second set of channel sheets; a sidewall spacer next to a sidewall of the metal gate, a thickness of the sidewall spacer covering the first and the second set of channel sheets at a top and sidewalls thereof; a first and a second source/drain (S/D) region at an end surface of the first and the second set of channel sheets respectively; and an isolation layer between a first sidewall of the first S/D region and a second sidewall of the second S/D region, where the isolation layer is directly adjacent to the sidewall spacer.

In one embodiment, the first and the second S/D region have a substantially rectangular shape of cross-section with a normal to the cross-section in a length direction of the metal gate.

In another embodiment, a width of the first S/D region is wider than a width of the first set of channel sheets, and a width of the second S/D region is wider than a width of the second set of channel sheets.

In one embodiment, the first and the second S/D region have a T-shaped cross-section with a normal to the cross-section in a length direction of the metal gate, the cross-section having a first width at a top portion and a second width at a bottom portion, the first width being wider than the second width.

In another embodiment, the second width at the bottom portion of the first and the second S/D region is substantially same as a width of the first and the second set of channel sheets. In one embodiment, the isolation layer includes one or more air gaps.

Embodiments of present invention provide a method. The method includes forming a first and a second raw stack of nanosheets on a substrate; forming a sacrificial gate surrounding the first and the second raw stack of nanosheets; forming a sidewall spacer at a sidewall of the sacrificial gate, a thickness of the sidewall spacer covering a portion of the first and the second raw stack of nanosheets; forming a first buffer layer at a first sidewall of the first raw stack of nanosheets and a second buffer layer at a second sidewall of the second raw stack of nanosheets, the first and the second buffer layer facing each other and directly adjacent to the sidewall spacer; forming an isolation layer between the first buffer layer and the second buffer layer; removing a portion of the first raw stack of nanosheets next to the first buffer layer to create a first opening; removing a portion of the second raw stack of nanosheets next to the second buffer layer to create a second opening; and forming a first source/drain (S/D) region in the first opening and a second S/D region in the second opening, the first S/D region being isolated from the second S/D region by the isolation layer.

In one embodiment, removing the first raw stack of nanosheets next to the first buffer layer creates a first set of nanosheets surrounded by the sacrificial gate, the first set of nanosheets includes a set of channel sheets and a set of sacrificial sheets, and the method further includes replacing the sacrificial gate and the set of sacrificial sheets with a metal gate to surround the set of channel sheets.

In another embodiment, forming the sidewall spacer at the sidewall of the sacrificial gate further includes forming the sidewall spacer at the first sidewall of the first raw stack of nanosheets and at the second sidewall of the second raw stack of nanosheets.

According to one embodiment, the method further includes, before forming the first and the second buffer layer, removing an upper portion of the sidewall spacer at the first sidewall of the first raw stack of nanosheets and an upper portion of the sidewall spacer at the second sidewall of the second raw stack of nanosheets.

In one embodiment, the first and the second opening, and the first and the second S/D region formed therein, have a T-shaped cross-section with a first width at a top and a second width at a bottom, the first width being wider than the second width.

In another embodiment, forming the isolation layer further includes forming one or more air gaps in the isolation layer.

According to another embodiment, the method further includes, before forming the first and the second buffer layer, removing the sidewall spacer at the first sidewall of the first raw stack of nanosheets and at the second sidewall of the second raw stack of nanosheets.

In one embodiment, the first and the second opening, and the first and the second S/D region formed therein, have a substantially rectangular shape of cross-section.

### BRIEF DESCRIPTION OF THE DRAWINGS

The present invention will be understood and appreciated more fully from the following detailed description of embodiments of present invention, taken in conjunction with accompanying drawings of which:

FIGS. 1A, 1B, 1C, and 1D to FIGS. 14A, 14B, 14C, and 14D are demonstrative illustrations of cross-sectional views and FIG. 1E to FIG. 14E are simplified top views of a semiconductor structure at various steps of manufacturing thereof according to one embodiment of present invention;

FIGS. 15A, 15B, 15C, and 15D to FIGS. 20A, 20B, 20C, and 20D are demonstrative illustrations of cross-sectional views and FIG. 15E to FIG. 20E are simplified top views of a semiconductor structure at various steps of manufacturing thereof according to another embodiment of present invention;

FIGS. 21A, 21B, 21C, and 21D are demonstrative illustrations of cross-sectional views and FIG. 21 is a simplified top view of a semiconductor structure at a step of manufacturing thereof according to yet another embodiment of present invention; and

FIG. 22 is a demonstrative illustration of a flow-chart of a method of manufacturing a semiconductor structure according to embodiments of present invention.

It will be appreciated that for simplicity and clarity purpose, elements shown in the drawings have not necessarily been drawn to scale. Further, and if applicable, in various functional block diagrams, two connected devices and/or elements may not necessarily be illustrated as being connected. In some other instances, grouping of certain elements in a functional block diagram may be solely for the purpose of description and may not necessarily imply that they are in a single physical entity, or they are embodied in a single physical entity.

### DETAILED DESCRIPTION

In the below detailed description and the accompanying drawings, it is to be understood that various layers, structures, and regions shown in the drawings are both demonstrative and schematic illustrations thereof that are not drawn to scale. In addition, for the case of explanation, one or more layers, structures, and regions of a type commonly used to form semiconductor devices or structures may not be explicitly shown in a given illustration or drawing. This does not imply that any layers, structures, and regions not explicitly shown are omitted from the actual semiconductor structures. Furthermore, it is to be understood that the embodiments discussed herein are not limited to the particular materials, features, and processing steps shown and described herein. In particular, with respect to semiconductor processing steps, it is to be emphasized that the descriptions provided herein are not intended to encompass all of the processing steps that may be required to form a functional semiconductor integrated circuit device. Rather, certain processing steps that are commonly used in forming semiconductor devices, such as, for example, wet cleaning and annealing steps, are purposefully not described herein for economy of description.

It is to be understood that the terms “about” or “substantially” as used herein with regard to thicknesses, widths, percentages, ranges, etc., are meant to denote being close or approximate to, but not exactly. For example, the term “about” or “substantially” as used herein implies that a small margin of error may be present such as, by way of example only, 1% or less than the stated amount. Likewise, the terms “on”, “over”, or “on top of” that are used herein to describe a positional relationship between two layers or structures are intended to be broadly construed and should not be interpreted as precluding the presence of one or more intervening layers or structures.

Moreover, although various reference numerals may be used across different drawings, the same or similar reference numbers are used throughout the drawings to denote the same or similar features, elements, or structures, and thus detailed explanations of the same or similar features, elements, or structures may not be repeated for each of the drawings for economy of description. Labelling for the same or similar elements in some drawings may be omitted as well in order not to overcrowd the drawings.

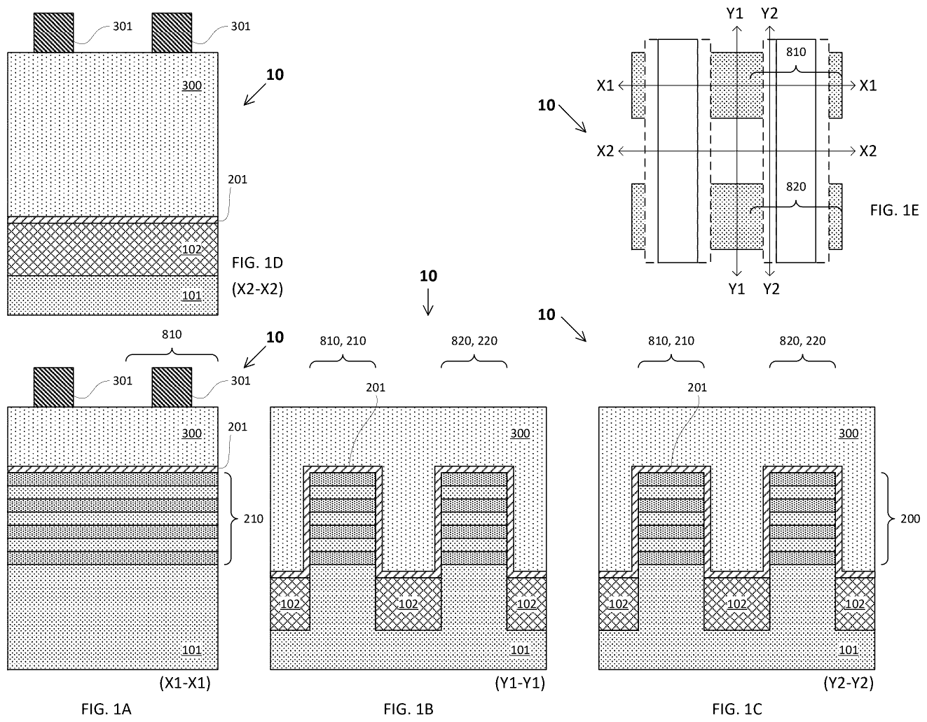

FIGS. 1A, 1B, 1C, and 1D are demonstrative illustrations of different cross-sectional views and FIG. 1E is a simplified top view of a semiconductor structure 10 in a step of manufacturing thereof according to one embodiment of present invention. More specifically, FIG. 1A illustrates a cross-sectional view of the semiconductor structure 10 with a cross-section made along a line X1-X1 as illustrated in FIG. 1E. In other words, the cross-section in FIG. 1A is made across the gate and the source/drain region in a direction along the length of the gate. FIG. 1B illustrates a cross-sectional view of the semiconductor structure 10 with a cross-section made along a line Y1-Y1 as illustrated in FIG. 1E. In other words, the cross-section in FIG. 1B is made across the source/drain region in a direction along the width of the gate. FIG. 1C illustrates a cross-sectional view of the semiconductor structure 10 with a cross-section made along a line Y2-Y2 as illustrated in FIG. 1E. In other words, the cross-section in FIG. 1C is made across the sidewall spacer of the gate in a direction along the width of the gate. FIG. 1D illustrates a cross-sectional view of the semiconductor structure 10 with a cross-section made along a line X2-X2 as illustrated in FIG. 1E. In other words, the cross-section in FIG. 1D is made outside the source/drain region in a direction along the length of the gate.

As its purpose is to show locations of the cross-sections illustrated in FIGS. 1A, 1B, 1C, and 1D, the simplified top view of FIG. 1E may selectively illustrate key features such as, for example, nanosheets, gates, source/drain regions, and sidewall spacers that were previously formed, are yet to be formed or whose views may be obscured by other elements. Features such as dielectric layers surrounding the above structures, dielectric caps, photomasks, etc. may not necessarily be illustrated in order not to overcrowd FIG. 1E, and to the extent that their omission from FIG. 1E does not hinder the description of embodiments of present invention, which are mainly provided hereinafter with reference to FIGS. 1A, 1B, 1C and 1D.

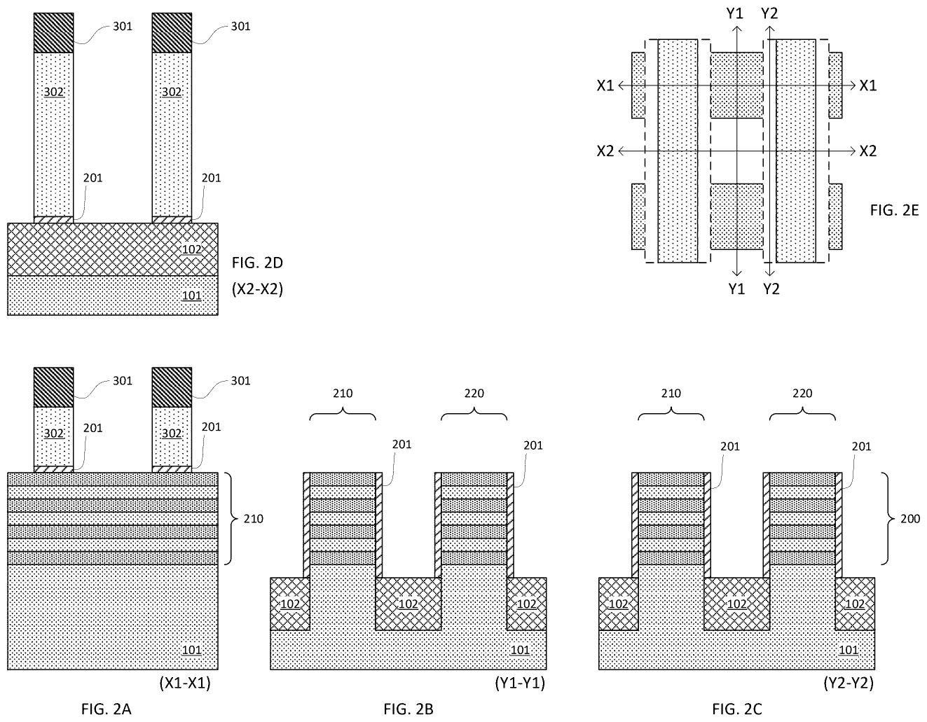

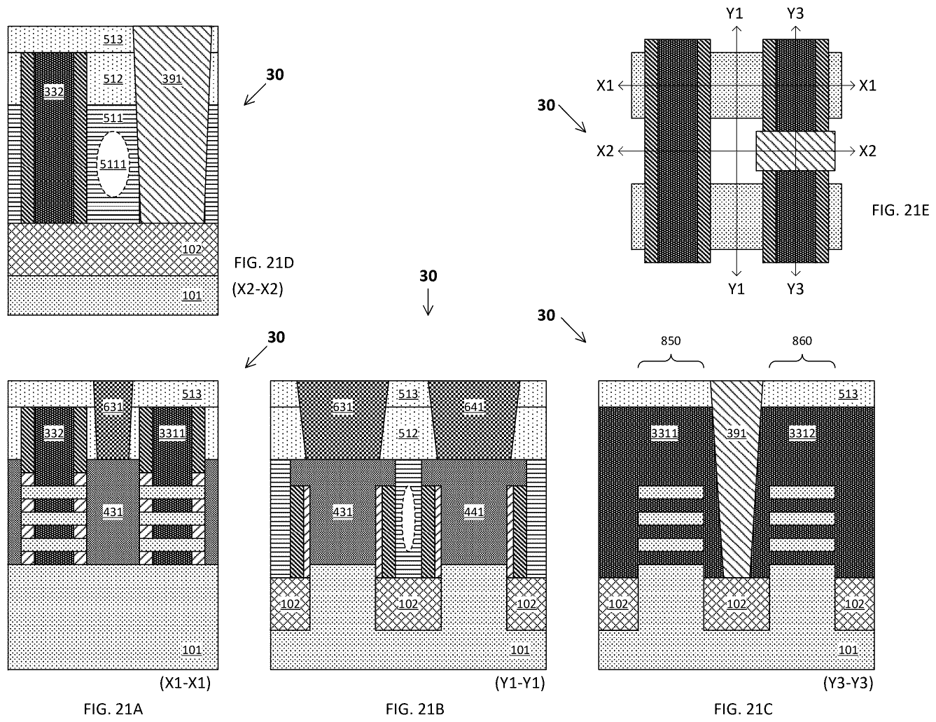

Likewise, FIGS. 2A, 2B, 2C, and 2D to FIGS. 21A, 21B, 21C, and 21D are demonstrative cross-sectional views and FIG. 2E to FIG. 21E are simplified top views of a semiconductor structure of the same or different embodiments, at different manufacturing steps, illustrated in manners similar to FIGS. 1A, 1B, 1C, 1D, and 1E respectively, with the exception of FIG. 21C. More particularly, FIG. 21C illustrates a cross-sectional view of a semiconductor structure with a cross-section made along a line Y3-Y3 as illustrated in FIG. 21E. In other words, the cross-section in FIG. 21C is made across the gate in a direction along the width of the gate.

Embodiments of present invention provide receiving or forming a semiconductor structure 10 that is demonstratively illustrated to include multiple sets of nanosheet transistors, including a first nanosheet transistor 810 and a second nanosheet transistor 820, although embodiments of present invention are not limited in this aspect and may be applied to other types of transistors and/or active devices. More particularly, the semiconductor structure 10 may include a semiconductor substrate 101 and one or more raw stacks of nanosheets 200 on top of the semiconductor substrate 101. The one or more raw stacks of nanosheets 200 may include, for example, a first raw stack of nanosheets 210 and a second raw stack of nanosheets 220. One or more shallow-trench-isolation (STI) structures 102 may be formed to be embedded in the semiconductor substrate 101 and in-between the one or more raw stacks of nanosheets 200.

The semiconductor substrate 101 may be a silicon (Si) substrate, a silicon-germanium (SiGe) substrate, a silicon-on-insulator (SOI) substrate, a silicon-germanium-on-insulator (SiGeOI) substrate, or other suitable substrates. The one or more raw stacks of nanosheets 200 may include a raw set of channel sheets placed alternately with a raw set of sacrificial sheets. The raw set of channel sheets may be, for example, a raw set of Si sheets and the raw set of sacrificial sheets may be, for example, a raw set of SiGe sheets as being discussed below in more details. The one or more STI structures 102 may be one or more layers of dielectric materials and the dielectric materials may include, for example, silicon-oxide (SiOx), silicon-nitride (SIN), silicon-carbide (SiC), silicoboron-carbonitride (SiBCN), silicon-oxycarbide (SiOC), silicon-oxycarbonitride (SiOCN), or other suitable dielectric materials.

In one embodiment, the one or more raw stacks of nanosheets 200 may be surrounded and/or covered by a dielectric liner 201, which may be, for example, a conformal layer of oxide such as a conformal layer of SiOx. The dielectric liner 201 may be formed on top of the one or more STI structures 102 as well between the one or more raw stacks of nanosheets 200 and may be materially different from the one or more STI structures 102. A sacrificial layer 300 may be formed on top of the dielectric liner 201 covering the one or more raw stacks of nanosheets 200. The sacrificial layer 300 may be made of amorphous silicon (a-Si), or other suitable materials and may be materially different from the dielectric liner 201.

Embodiments of present invention further provide forming a set of gate masks 301, such as a set of SiN hard masks, on top of the sacrificial layer 300 in a process of forming a set of sacrificial gates, as being described below in more details.

FIGS. 2A, 2B, 2C, and 2D are demonstrative illustrations of different cross-sectional views and FIG. 2E is a simplified top view of a semiconductor structure in a step of manufacturing thereof according to one embodiment of present invention. More specifically, following the step illustrated in FIGS. 1A, 1B, 1C, 1D, and 1E, embodiments of present invention provide transferring a pattern of the set of gate masks 301 onto the sacrificial layer 300 by removing portions of the sacrificial layer 300 not covered by the set of gate masks 301 through a selective etch process such as a reactive-ion-etch (RIE) process. The RIE process also removes portions of the dielectric liner 201 underneath the removed portions of the sacrificial layer 300 until the STI structures 102 underneath the dielectric liner 201 are exposed. The RIE process forms a set of sacrificial gates 302 that are oriented in a direction substantially perpendicular to a longitudinal direction of the one or more raw stacks of nanosheets 200.

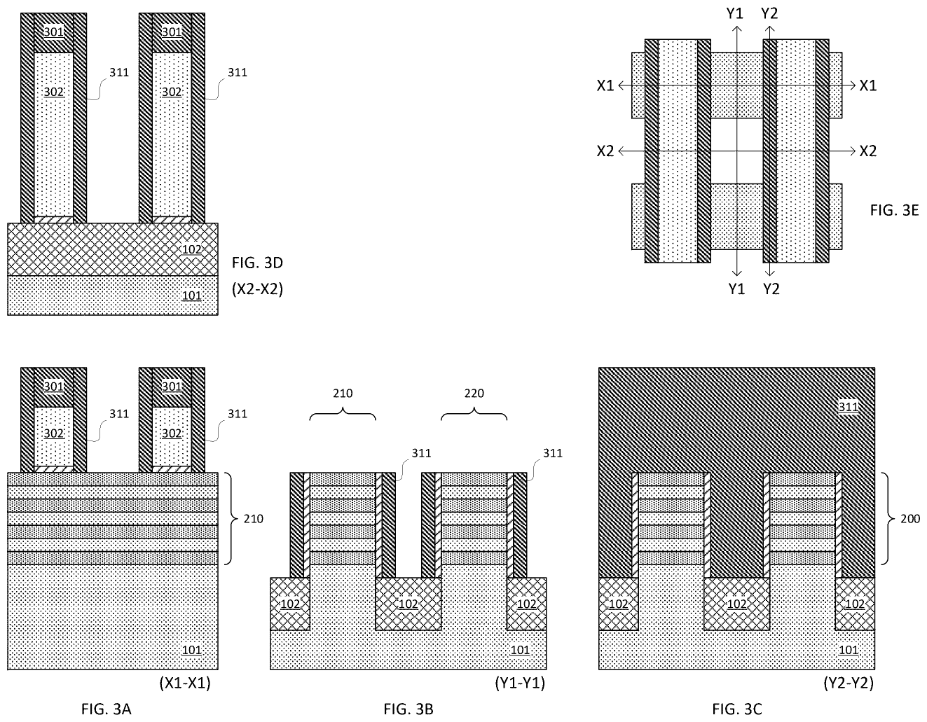

FIGS. 3A, 3B, 3C, and 3D are demonstrative illustrations of different cross-sectional views and FIG. 3E is a simplified top view of a semiconductor structure in a step of manufacturing thereof according to one embodiment of present invention. More specifically, following the step illustrated in FIGS. 2A, 2B, 2C, 2D, and 2E, embodiments of present invention provide forming one or more pairs of sidewall spacers 311 at sidewalls of the set of sacrificial gates 302. For example, embodiments of present invention provide first forming a conformal layer of dielectric material such as, for example, SiOx, SiN, SiC, SiBCN, SiOC, and SiOCN that is suitable for the sidewall spacers to cover the set of sacrificial gates 302. The conformal layer of dielectric material may also cover the exposed portions of the one or more STI structures 102 in-between the set of sacrificial gates 302. Subsequently, a directional and/or anisotropic etch process, such as a RIE process, may be applied to etch and remove horizontal portions of the conformal layer of dielectric material, leaving only vertical portions of the conformal layer of dielectric material at sidewalls of the set of sacrificial gates 302 to form sidewall spacers 311 as is demonstratively illustrated in FIG. 3C. Vertical portions of the conformal layer of dielectric material may also remain at sidewalls of the first raw stack of nanosheets 210 and the second raw stack of nanosheets 220, via the dielectric liner 201, thereby forming the sidewall spacers 311 as is demonstratively illustrated in FIG. 3B. A thickness of the sidewall spacers 311 at the sidewalls of the set of sacrificial gates 302 may also cover or surround a top and sidewalls of the first raw stack of nanosheets 210 and the second raw stack of nanosheets 220, at least a portion thereof and via the dielectric liner 201, as is demonstratively illustrated in FIG. 3C and FIG. 3E.

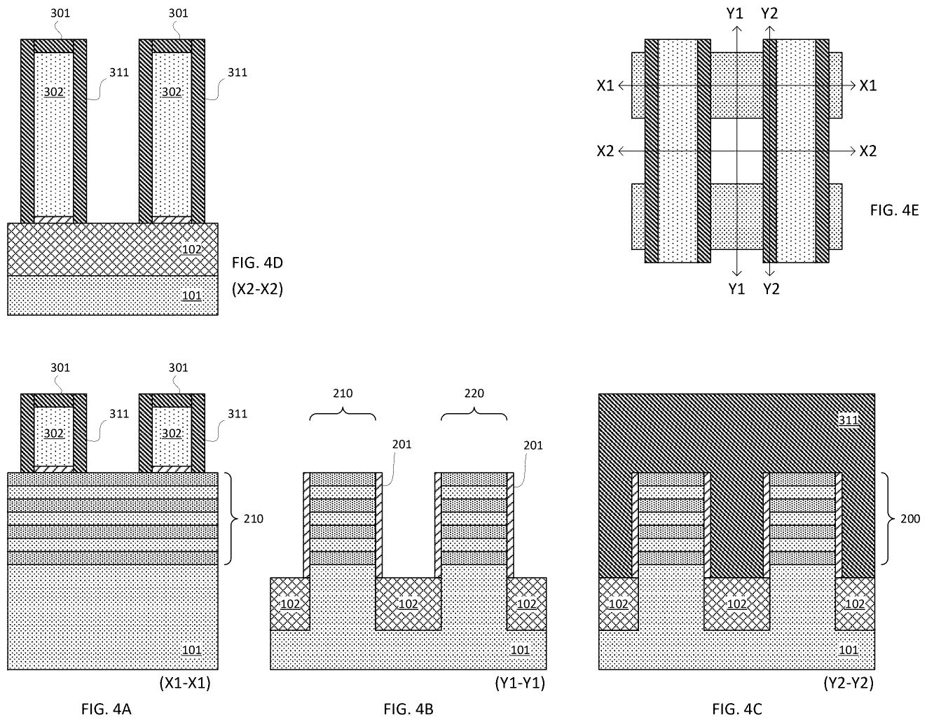

FIGS. 4A, 4B, 4C, and 4D are demonstrative illustrations of different cross-sectional views and FIG. 4E is a simplified top view of a semiconductor structure in a step of manufacturing thereof according to one embodiment of present invention. More specifically, following the step illustrated in FIGS. 3A, 3B, 3C, 3D, and 3E, embodiments of present invention provide continuing applying a directional and/or anisotropic etch process to remove portions of the sidewall spacers 311 that are at the sidewalls of the first raw stack of nanosheets 210 and the second raw stack of nanosheets 220 as is demonstratively illustrated in FIG. 4B. For example, a RIE etch process may be applied to remove the sidewall spacer 311 at a first sidewall of the first raw stack of nanosheets 210 and at a second sidewall of the second raw stack of nanosheets 220 where the first and the second sidewalls of the first and the second raw stack of nanosheets 210 and 220 face each other. In the meantime, sidewalls of the first raw stack of nanosheets 210 and the second raw stack of nanosheets 220, adjacent to the sidewalls of the set of sacrificial gates 302, remain covered by the sidewall spacers 311 formed next to the set of sacrificial gates 302, as is demonstratively illustrated in FIG. 4C. This directional and/or anisotropic etch process may, to certain extent, reduce the height of the set of gate masks 301 as is demonstratively illustrated in FIG. 4A and FIG. 4D.

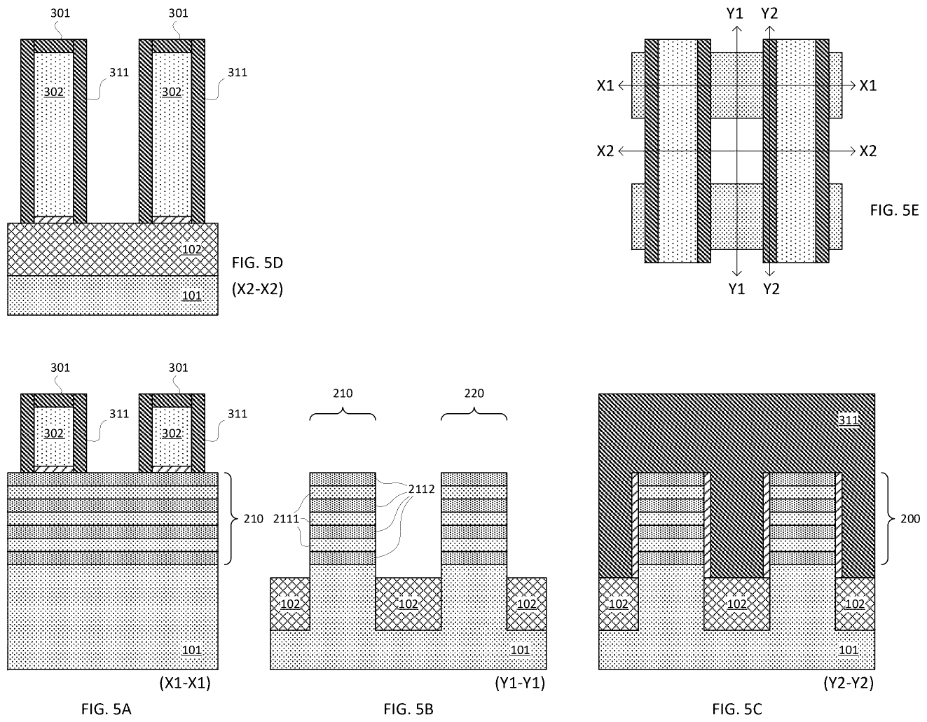

FIGS. 5A, 5B, 5C, and 5D are demonstrative illustrations of different cross-sectional views and FIG. 5E is a simplified top view of a semiconductor structure in a step of manufacturing thereof according to one embodiment of present invention. More specifically, following the step illustrated in FIGS. 4A, 4B, 4C, 4D, and 4E, embodiments of present invention provide removing the dielectric liner 201, at the sidewalls of the first raw stack of nanosheets 210 and the second raw stack of nanosheets 220, exposed by the removal of the sidewall spacers 311. The removal of the dielectric liner 201 subsequently exposes the first raw stack of nanosheets 210 and the second raw stack of nanosheets 220. As being discussed above, the first and the second raw stack of nanosheets 210 and 220 may each be formed to include a raw set of channel sheets 2111 and a raw set of sacrificial sheets 2112 with each sacrificial sheet being placed on top of each channel sheet or vice versus. In other words, the channel sheets 2111 and sacrificial sheets 2112 may be placed one on top of another in an alternating manner.

In one embodiment, the raw set of channel sheets 2111 may be a set of Si sheets and the raw set of sacrificial sheets 2112 may be a set of SiGe sheets. The SiGe sheets may include Ge content of some desired or pre-determined percentage in a range, for example, between about 20 at. % and about 50 at. % so as to have an etch selectivity that is different from that of the Si sheets. For example, in one aspect, the first raw stack of nanosheets 210 may include a set of Si sheets that is placed alternately with a set of SiGe sheets. Later, in a replacement-metal-gate (RMG) process, the set of SiGe sheets may be selectively removed to create an opening, which is then filled with a gate dielectric, one or more work-function-metals, and a conductive material to form a metal gate surrounding the set of Si sheets. Here, it is to be noted that embodiments of present invention are not limited in this aspect and the raw set of channel sheets 2111 and the raw set of sacrificial sheets 2112 may be made of or contain other types of material, in addition to Si or SiGe.

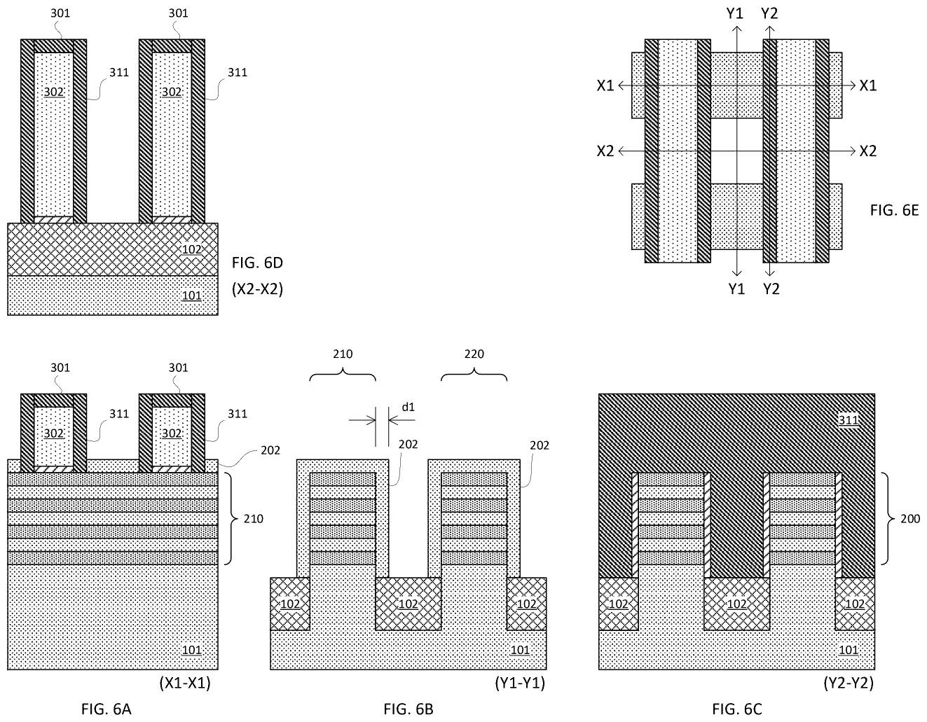

FIGS. 6A, 6B, 6C, and 6D are demonstrative illustrations of different cross-sectional views and FIG. 6E is a simplified top view of a semiconductor structure in a step of manufacturing thereof according to one embodiment of present invention. More specifically, following the step illustrated in FIGS. 5A, 5B, 5C, 5D, and 5E, embodiments of present invention provide epitaxially growing a buffer layer 202 at the exposed top surfaces and sidewall surfaces of the first raw stack of nanosheets 210 and the second raw stack of nanosheets 220. As the set of sacrificial gates 302 and the sidewall spacers 311 cover portions of the first and the second raw stack of nanosheets 210 and 220 that are immediately adjacent to the set of sacrificial gates 302, the buffer layer 202 may be formed on portions of the one or more raw stacks of nanosheets 200 that are not covered by the sidewall spacers 311 and not by the set of sacrificial gates 302. The buffer layer 202 may be a layer of Si or SiGe that may be epitaxially grown from the one or more raw stacks of nanosheets 200 such as from sidewalls of the first and the second raw stack of nanosheets 210 and 220. The buffer layer 202 may not epitaxially grow on top of the one or more STI structures 102 due to material differences. The buffer layer 202 may be grown to be a conformal layer with a thickness d1 ranging between about 5 nm and about 20 nm.

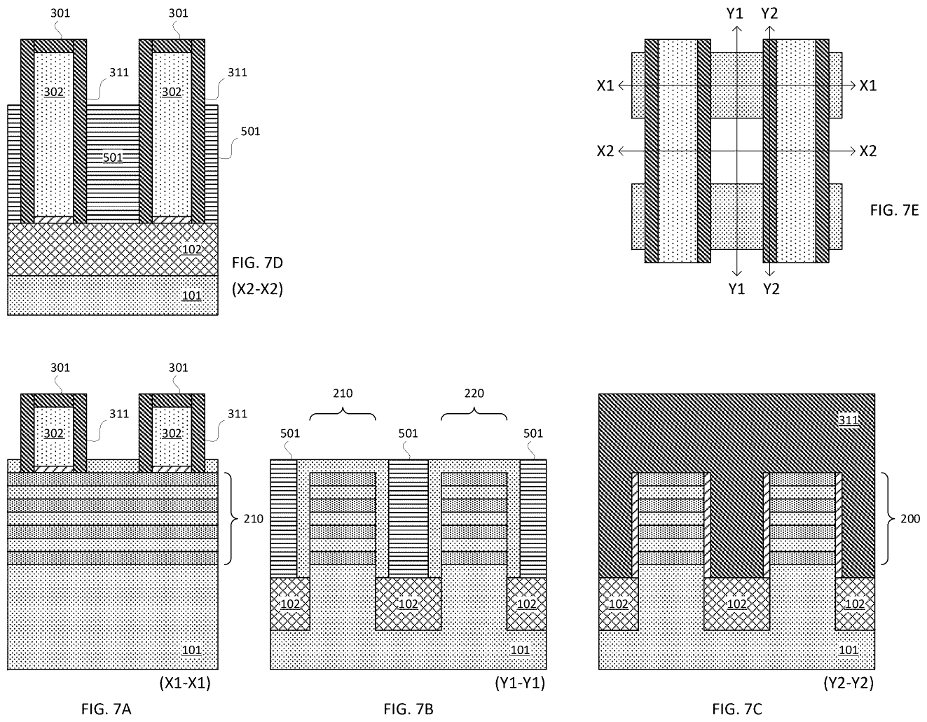

FIGS. 7A, 7B, 7C, and 7D are demonstrative illustrations of different cross-sectional views and FIG. 7E is a simplified top view of a semiconductor structure in a step of manufacturing thereof according to one embodiment of present invention. More specifically, following the step illustrated in FIGS. 6A, 6B, 6C, 6D, and 6E, embodiments of present invention provide forming an isolation layer 501, on top of the one or more STI structures 102, that fills gaps between the one or more raw stacks of nanosheets 200. For example, a layer of dielectric material may first be deposited through, for example, a chemical-vapor-deposition (CVD) process, a physical-vapor-deposition (PVD) process, or an atomic-layer-deposition (ALD) process, to cover the one or more STI structures 102; the first and the second raw stack of nanosheets 210 and 220; and the set of sacrificial gates 302. Next, a chemical-mechanical-polishing (CMP) process may be applied to planarize a top surface of the layer of dielectric material. After the planarization, a selective etch process may be applied to recess thereby reduce the height of the layer of dielectric material until the layer of dielectric material becomes the isolation layer 501 with a top surface that is, for example, substantially coplanar with top surfaces of the buffer layer 202. In one embodiment, the isolation layer 501 may include or may be made of SiOx, SiN, SiC, SiBCN, SiOC, and SiOCN or other suitable and/or low-k dielectric materials.

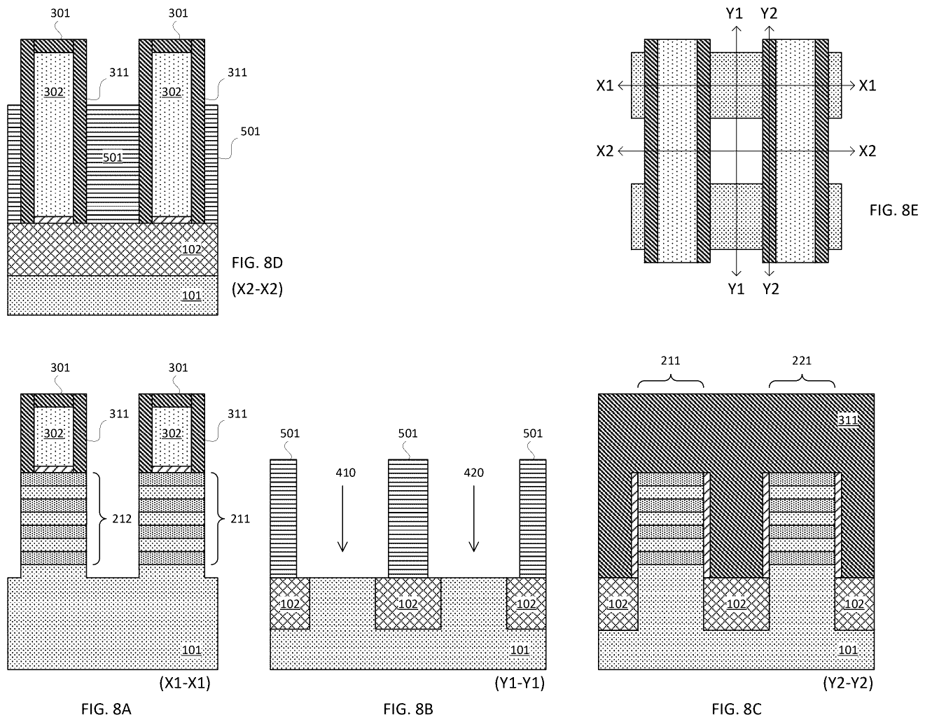

FIGS. 8A, 8B, 8C, and 8D are demonstrative illustrations of different cross-sectional views and FIG. 8E is a simplified top view of a semiconductor structure in a step of manufacturing thereof according to one embodiment of present invention. More specifically, following the step illustrated in FIGS. 7A, 7B, 7C, 7D, and 7E, embodiments of present invention provide recessing the first raw stack of nanosheets 210 and the second raw stack of nanosheets 220 that are exposed between the set of sacrificial gates 302 to create multiple sets of nanosheets. For example, a selective etch process may be applied to remove portions of the first raw stack of nanosheets 210 thereby creating a first set of nanosheets 211 and a third set of nanosheets 212. Similarly, the second raw stack of nanosheets 220 may be recessed to create several sets of nanosheets including a second set of nanosheets 221 and a fourth set of nanosheets. Removing portions of the first and the second raw stack of nanosheets 210 and 220, selective to the isolation layer 501, may thus create a first opening 410 and a second opening 420 that are self-aligned with the isolation layer 501. The first and the second opening 410 and 420 may expose end surfaces of the multiple sets of nanosheets such as end surfaces of the first set of nanosheets 211 and the second set of nanosheets 221. The first and the second opening 410 and 420 may be used to form source/drain (S/D) regions of the first and the second nanosheet transistor 810 and 820. The S/D regions formed thereby may be isolated from each other by the isolation layer 501, as being described below in more details. In one embodiment, the first and the second opening 410 and 420 may have a substantially rectangular shape of cross-section and may have a width that is wider than the width of the first and the second set of nanosheets 211 and 221.

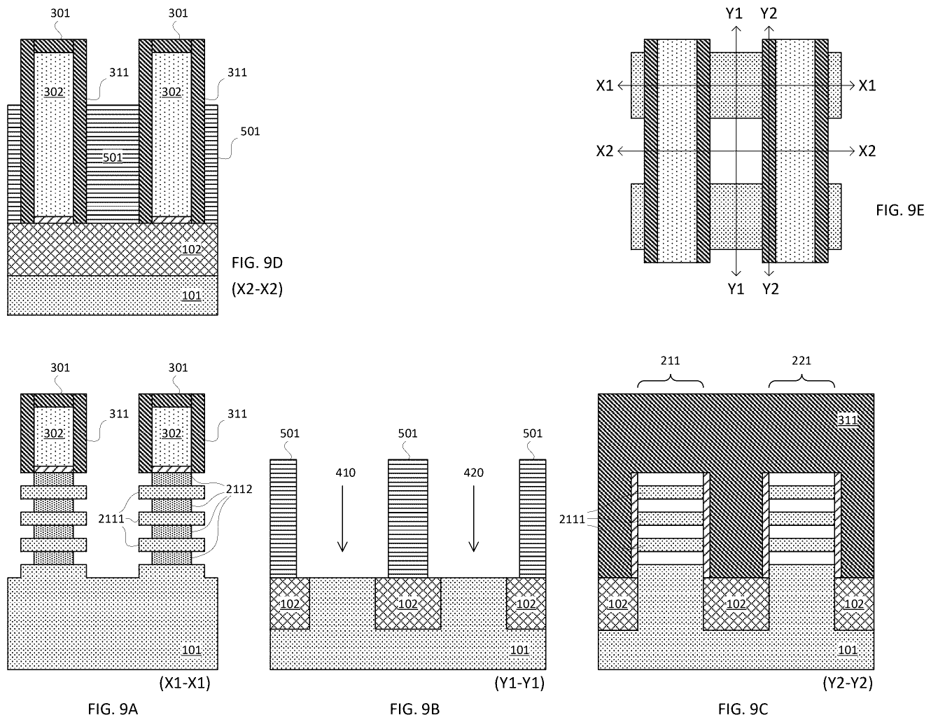

FIGS. 9A, 9B, 9C, and 9D are demonstrative illustrations of different cross-sectional views and FIG. 9E is a simplified top view of a semiconductor structure in a step of manufacturing thereof according to one embodiment of present invention. More specifically, following the step illustrated in FIGS. 8A, 8B, 8C, 8D, and 8E, embodiments of present invention provide performing indentation at the set of sacrificial sheets 2112 between the set of channel sheets 2111 in each of the multiple sets of nanosheets. The indentation may create indents at the longitudinal ends of the set of sacrificial sheets 2112 of, for example, SiGe sheets as is demonstratively illustrated in FIG. 9A, between the set of channel sheets 2111 of, for example, Si sheets. The indents may subsequently be filled with a dielectric material to form inner spacers as being described below in more details.

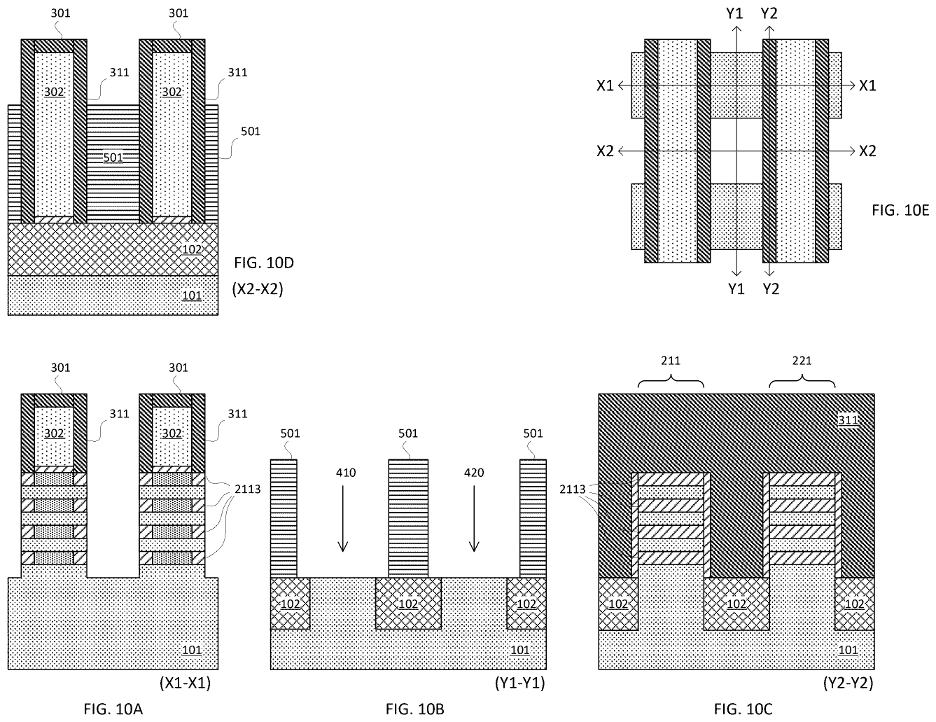

FIGS. 10A, 10B, 10C, and 10D are demonstrative illustrations of different cross-sectional views and FIG. 10E is a simplified top view of a semiconductor structure in a step of manufacturing thereof according to one embodiment of present invention. More specifically, following the step illustrated in FIGS. 9A, 9B, 9C, 9D, and 9E, embodiments of present invention provide filling the indents at the longitudinal ends of the set of sacrificial sheets 2112 with a dielectric material to form a plurality of inner spacers 2113. For example, a conformal dielectric layer may first be deposited along the sidewalls of the set of nanosheets 211. The conformal dielectric layer may pinch off inside the indents to fully fill the indents. The portions of conformal dielectric layer that are outside the indents may then be selectively removed or etched away, through a directional and/or anisotropic etch process, resulting in rest of the conformal dielectric layer to remain inside the indents to form the plurality of inner spacers 2113.

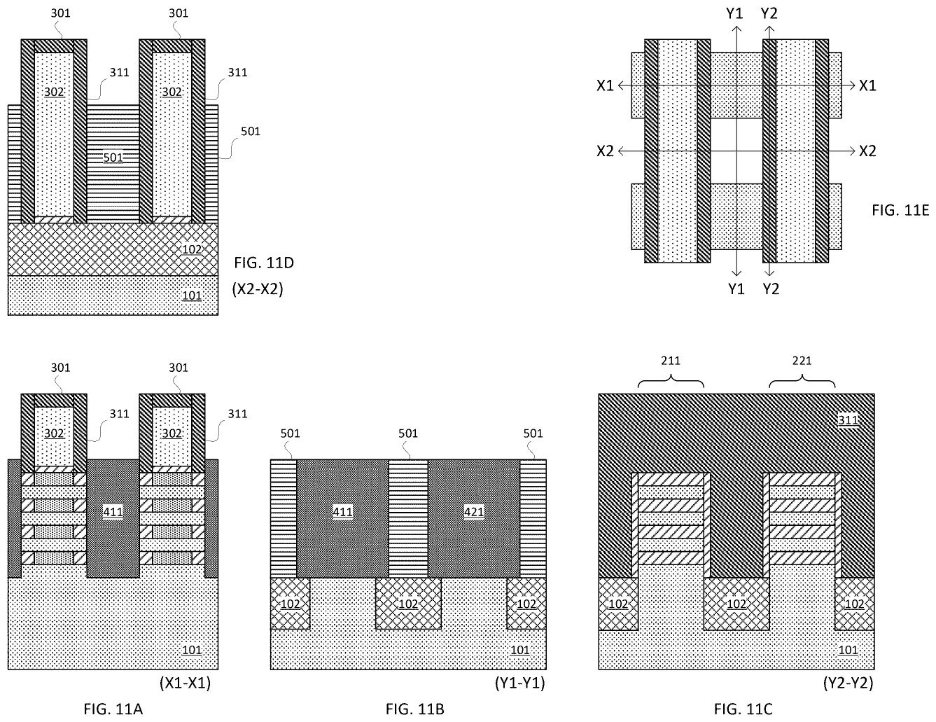

FIGS. 11A, 11B, 11C, and 11D are demonstrative illustrations of different cross-sectional views and FIG. 11E is a simplified top view of a semiconductor structure in a step of manufacturing thereof according to one embodiment of present invention. More specifically, following the step illustrated in FIGS. 10A, 10B, 10C, 10D, and 10E, embodiments of present invention provide forming S/D regions at the longitudinal ends of the channel sheets of the multiple sets of nanosheets. For example, a first S/D region 411 may be formed, through an epitaxial growth process, from end surfaces of the set of channel sheets 2111 of the set of nanosheets 211. The first S/D region 411 formed thereby may fill the first opening 410 to be self-aligned to the surrounding isolation layer 501. Similarly, a second S/D region 421 may be formed through the same epitaxial growth process to fill the second opening 420 and be self-aligned to the isolation layer 501. In other words, the first and the second S/D region 411 and 421 may be isolated from each other by the isolation layer 501. The first and the second S/D region 411 and 421 so formed may have a substantially rectangular shape of cross-section, following the shape of the first and the second opening 410 and 420. A normal to the cross-section may be along a length direction of the sacrificial gates 302, and the metal gate to be formed later. The first and the second S/D region 411 and 421 may have a width that is wider than that of the first and the second set of nanosheets 211 and 221.

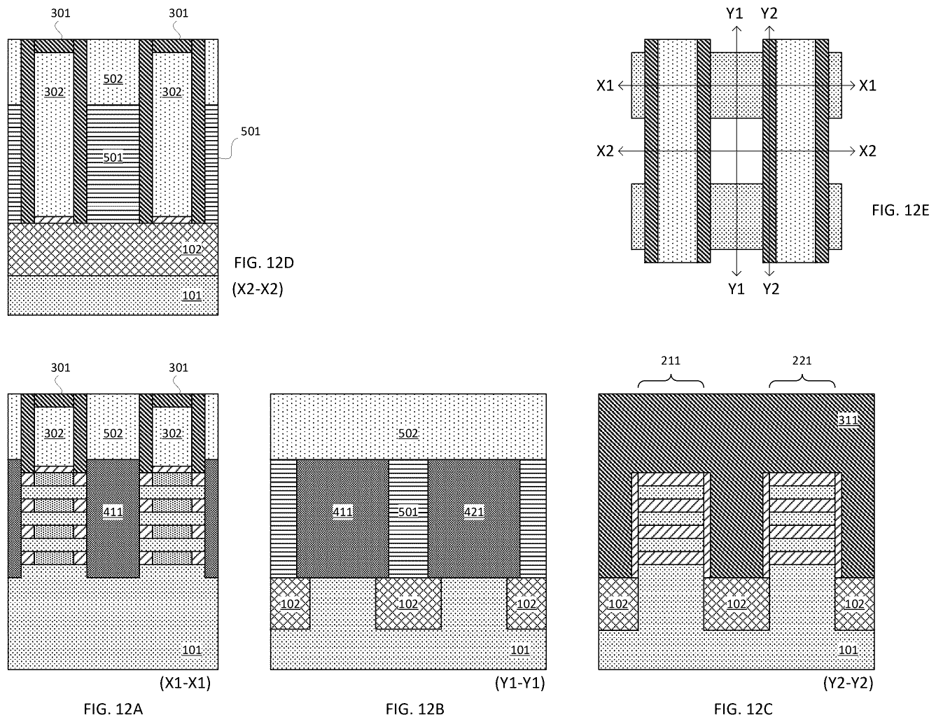

FIGS. 12A, 12B, 12C, and 12D are demonstrative illustrations of different cross-sectional views and FIG. 12E is a simplified top view of a semiconductor structure in a step of manufacturing thereof according to one embodiment of present invention. More specifically, following the step illustrated in FIGS. 11A, 11B, 11C, 11D, and 11E, embodiments of present invention provide forming an inter-level dielectric (ILD) layer 502 on top of the first and the second S/D region 411 and 421 and on top of the isolation layer 501. For example, a dielectric material may be deposited in between and on top of the set of sacrificial gates 302. A CMP process may be subsequently applied to planarize a top surface of the dielectric layer until, for example, the gate masks 301 are exposed thereby resulting in the ILD layer 502. In one embodiment, the ILD layer 502 may include or may be made of SiOx, SiN, SiC, SiBCN, SiOC, and SiOCN, and may preferably be made of low-k dielectric materials.

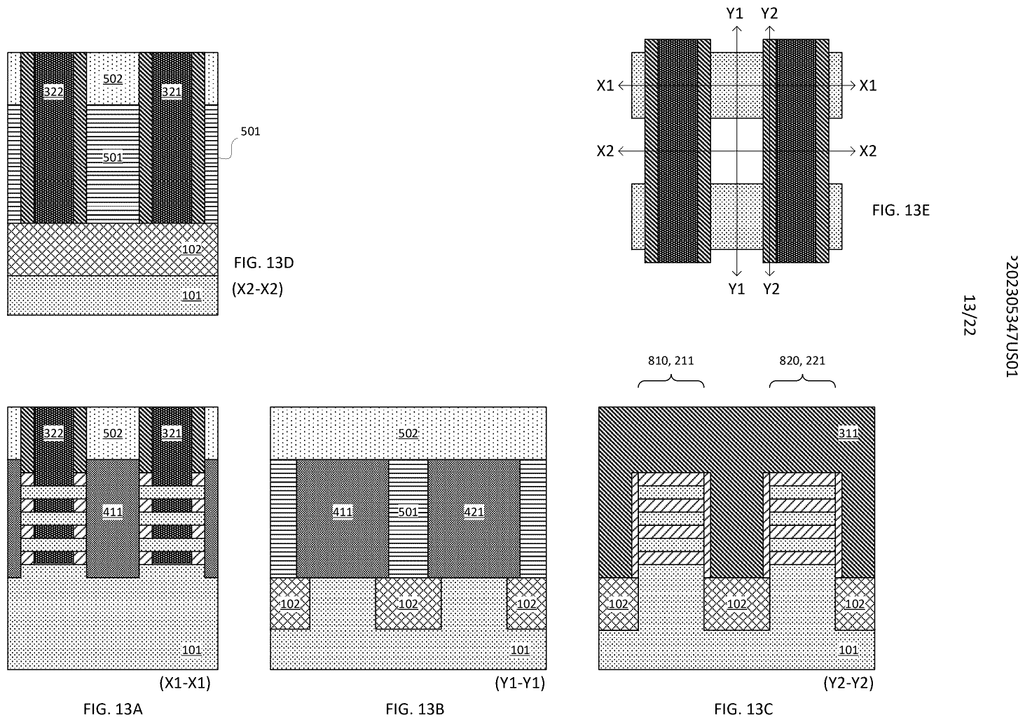

FIGS. 13A, 13B, 13C, and 13D are demonstrative illustrations of different cross-sectional views and FIG. 13E is a simplified top view of a semiconductor structure in a step of manufacturing thereof according to one embodiment of present invention. More specifically, following the step illustrated in FIGS. 12A, 12B, 12C, 12D, and 12E, embodiments of present invention provide performing a replacement-metal-gate (RMG) process to form a set of metal gates of the multiple sets of nanosheet transistors. More particularly, embodiments of present invention provide removing the set of gate masks 301 through, for example, a CMP process or other selective etch process to expose the set of sacrificial gates 302. Next, embodiments of present invention provide removing the set of sacrificial gates 302, the dielectric liner 201 underneath thereof, and the set of sacrificial sheets 2112 through, for example, one or more selective etch processes to create a first opening exposing the set of channel sheets 2111 of the first set of nanosheets 211. Embodiments of present invention further provide filling the first opening with a gate dielectric, one or more work-function-metal (WFM) layers, and one or more gate metals of conductive materials to surround the set of channel sheets 2111 thereby forming a first metal gate 321. In one embodiment, the first metal gate 321 may be a shared metal gate that is shared by the first nanosheet transistor 810 and the second nanosheet transistor 820. Similarly, through the same RMG process, a second opening may be created that exposes the set of channel sheets of the second set of nanosheets 221, and a gate dielectric, one or more WFM layers and one or more gate metals may be formed to surround the set of channel sheets thereby forming a second metal gate 322. The second metal gate 322 may be a shared metal gate as well. The one or more conductive materials may include, for example, aluminum (Al), tungsten (W), and/or other suitable conductive materials.

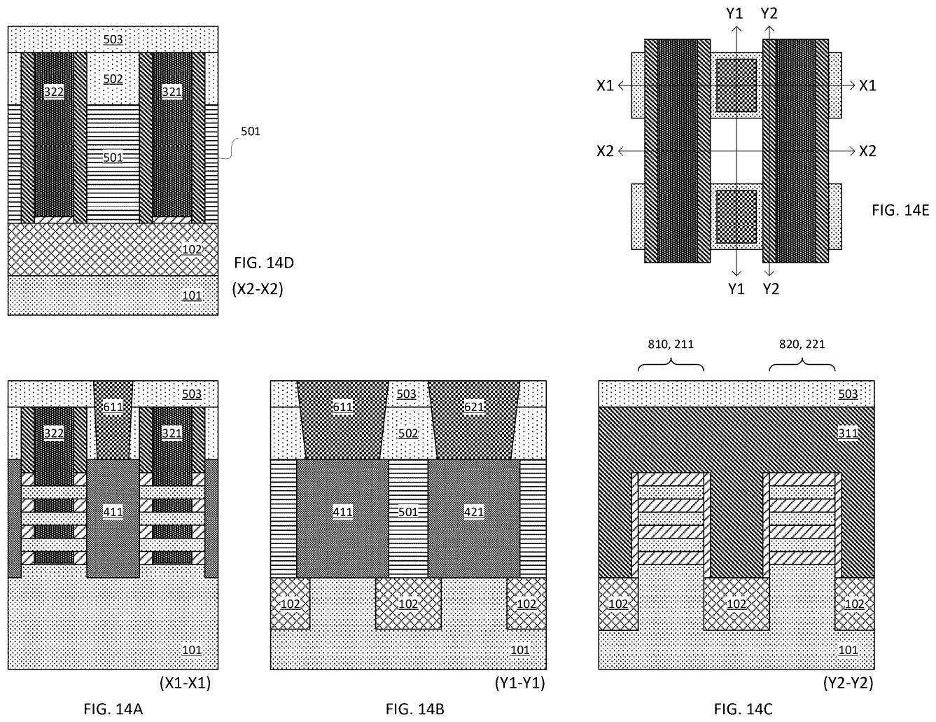

FIGS. 14A, 14B, 14C, and 14D are demonstrative illustrations of different cross-sectional views and FIG. 14E is a simplified top view of a semiconductor structure in a step of manufacturing thereof according to one embodiment of present invention. More specifically, following the step illustrated in FIGS. 13A, 13B, 13C, 13D, and 13E, embodiments of present invention provide forming an ILD layer 503 on top of the first and the second metal gates 321 and 322 and on top of the ILD layer 502. In one embodiment, the ILD layer 503 may include or be made of SiOx, SiN, SiC, SiBCN, SiOC, and SiOCN, and may preferably be made of low-k dielectric materials. In one embodiment, the ILD layer 503 may be substantially same, materially, as the ILD layer 502.

Subsequently, one or more S/D contacts and/or gate contacts may be formed through the ILD layer 503 and/or the ILD layer 502 to be in contact with S/D regions and/or metal gates such as, for example, the first and the second S/D region 411 and 421 and the first and the second metal gates 321 and 322 of the first and the second nanosheet transistor 810 and 820. For example, one or more openings may be created through a lithographic patterning and etch process in the ILD layer 503 and 502. The one or more openings may subsequently be filled with conductive materials, such as Cu, Al, Ru, Co, and/or W to form a first S/D contact 611 contacting the first S/D region 411 and a second S/D contact 621 contacting the second S/D region 421.

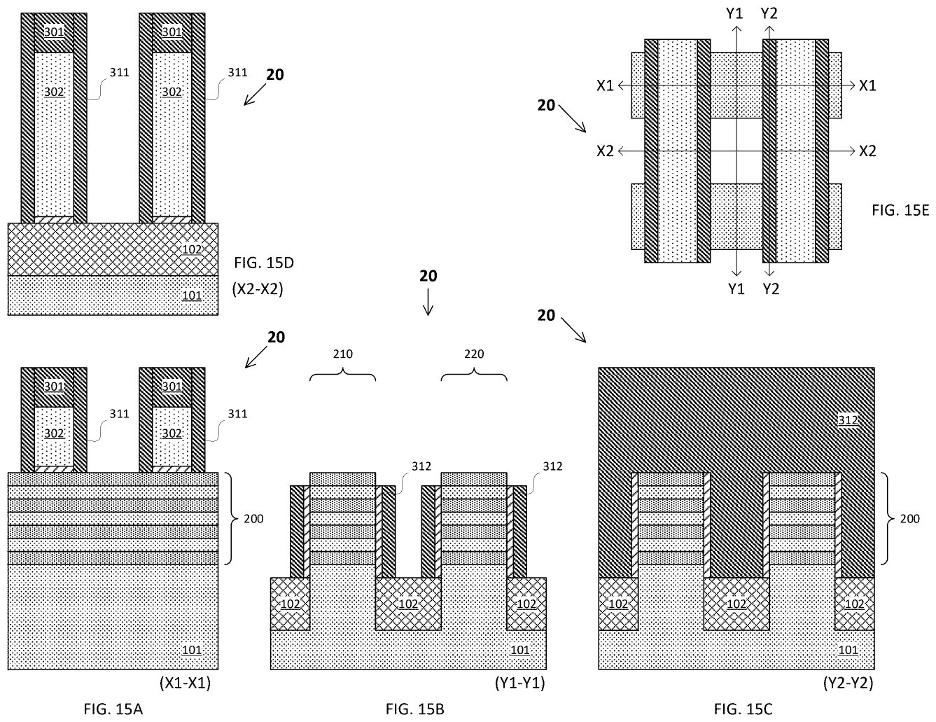

FIGS. 15A, 15B, 15C, and 15D to FIGS. 20A, 20B, 20C, and 20D are demonstrative illustrations of cross-sectional views and FIG. 15E to FIG. 20E are simplified top views of a semiconductor structure 20 at various steps of manufacturing thereof according to another embodiment of present invention.

More particularly, FIGS. 15A, 15B, 15C, and 15D are demonstrative illustrations of different cross-sectional views and FIG. 15E is a simplified top view of a semiconductor structure 20 in a step of manufacturing thereof according to one embodiment of present invention. Following the step illustrated in FIGS. 3A, 3B, 3C, 3D, and 3E, embodiments of present invention provide continuing applying the directional and/or anisotropic etch process to remove an upper portion of the sidewall spacers 311, and the dielectric liner 201 underneath thereof, at the sidewalls of the first raw stack of nanosheets 210 and the second raw stack of nanosheets 220, resulting in sidewall spacers 312 from the remaining portion of the sidewall spacers 311 as is demonstratively illustrated in FIG. 15B. The sidewall spacers 312 may be compared with the embodiment demonstratively illustrated in FIG. 4B where the sidewall spacers 311 are substantially removed from sidewalls of the first and the second raw stack of nanosheets 210 and 220. The removal of only the upper portion of the sidewall spacers 311 exposes a portion of the first and the second raw stack of nanosheets 210 and 220, from which an epitaxial buffer layer may be formed through an epitaxial growth process.

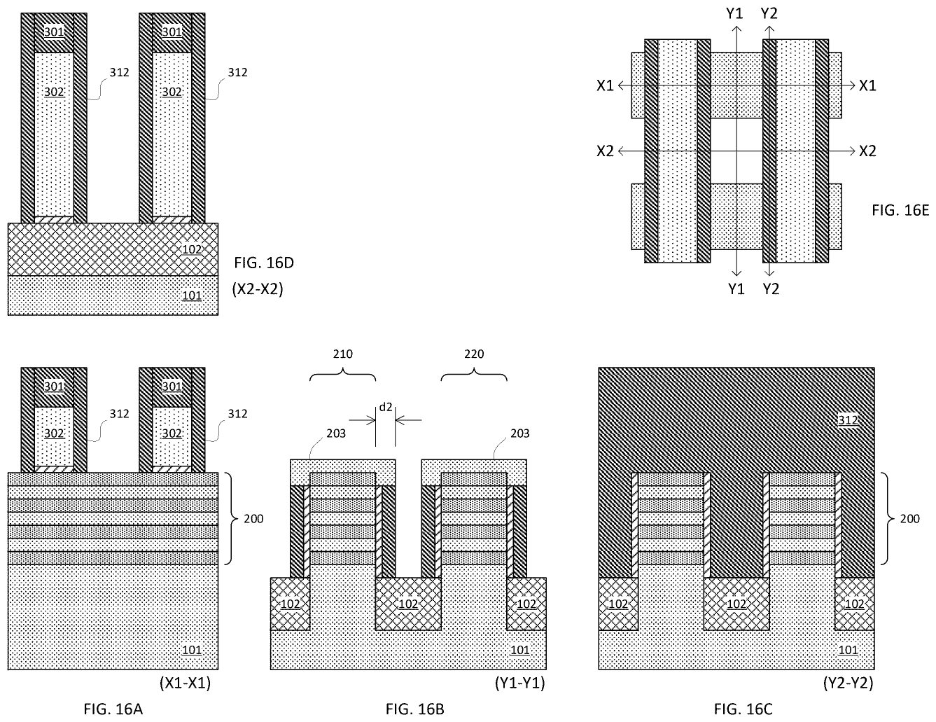

FIGS. 16A, 16B, 16C, and 16D are demonstrative illustrations of different cross-sectional views and FIG. 16E is a simplified top view of a semiconductor structure in a step of manufacturing thereof according to one embodiment of present invention. More specifically, following the step illustrated in FIGS. 15A, 15B, 15C, 15D, and 15E, embodiments of present invention provide epitaxially growing a buffer layer 203 at the exposed top surfaces and upper portion of sidewall surfaces of the first and the second raw stack of nanosheets 210 and 220. The buffer layer 203 may be formed to have a thickness d2, at the sidewalls of the first and the second raw stack of nanosheets 210 and 220, that is substantially same as a combined thickness of the sidewall spacers 312 and the dielectric liner 201. However, embodiments of present invention are not limited in this aspect and the thickness of the buffer layer 203 may be bigger or smaller than the sum of the sidewall spacers 312 and the dielectric liner 201. In one embodiment, the buffer layer 203 may be grown to have the thickness d2 ranging from about 5 nm to about 20 nm. On the other hand, the buffer layer 203 may not grow from the sidewall spacers 312, neither from the one or more STI structures 102, both of which are dielectric materials while the buffer layer 203 may be a layer of Si or SiGe.

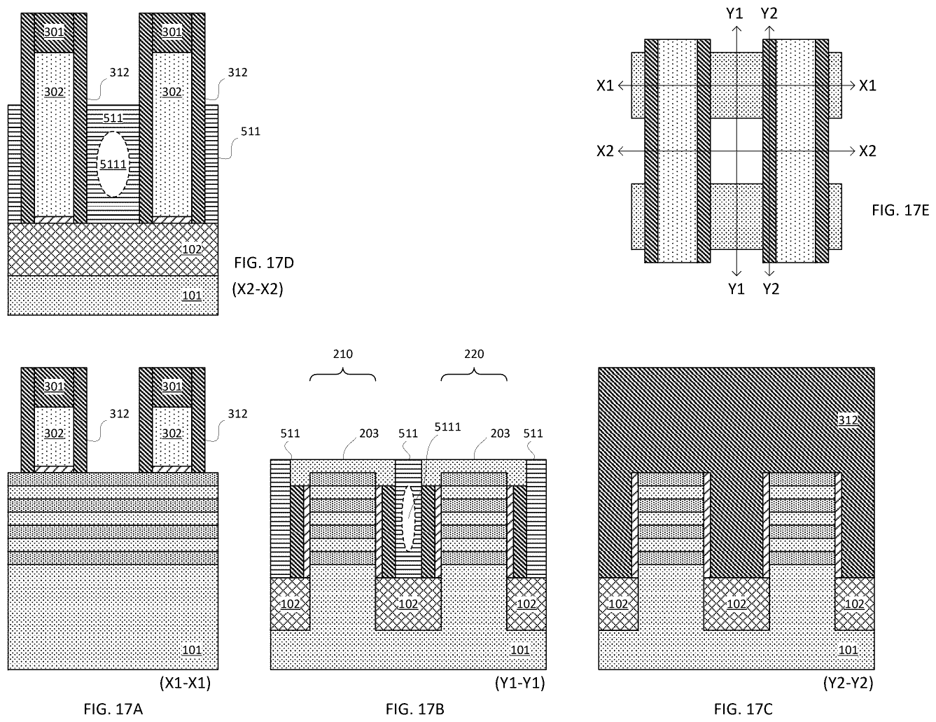

FIGS. 17A, 17B, 17C, and 17D are demonstrative illustrations of different cross-sectional views and FIG. 17E is a simplified top view of a semiconductor structure in a step of manufacturing thereof according to one embodiment of present invention. More specifically, following the step illustrated in FIGS. 16A, 16B, 16C, 16D, and 16E, embodiments of present invention provide forming an isolation layer 511 on top of the one or more STI structures 102, filling the gaps between the one or more raw stacks of nanosheets 200. Because of the narrowed spacing between the one or more raw stacks of nanosheets 200, in one embodiment, one or more air gaps may be formed inside the isolation layer 511. The isolation layer 511 may include or be made of, for example, SiOx, SiN, SiC, SiBCN, SiOC, SiOCN or other suitable low-k dielectric materials. The isolation layer 511 may be formed through a CVD process, a PVD process, or an ALD process to a level above the gate masks 301 on top of the set of sacrificial gates 302. Next, a CMP process may be applied to planarize a top surface of the isolation layer 511, which is then recessed until, for example, top surfaces of the buffer layer 203 are exposed.

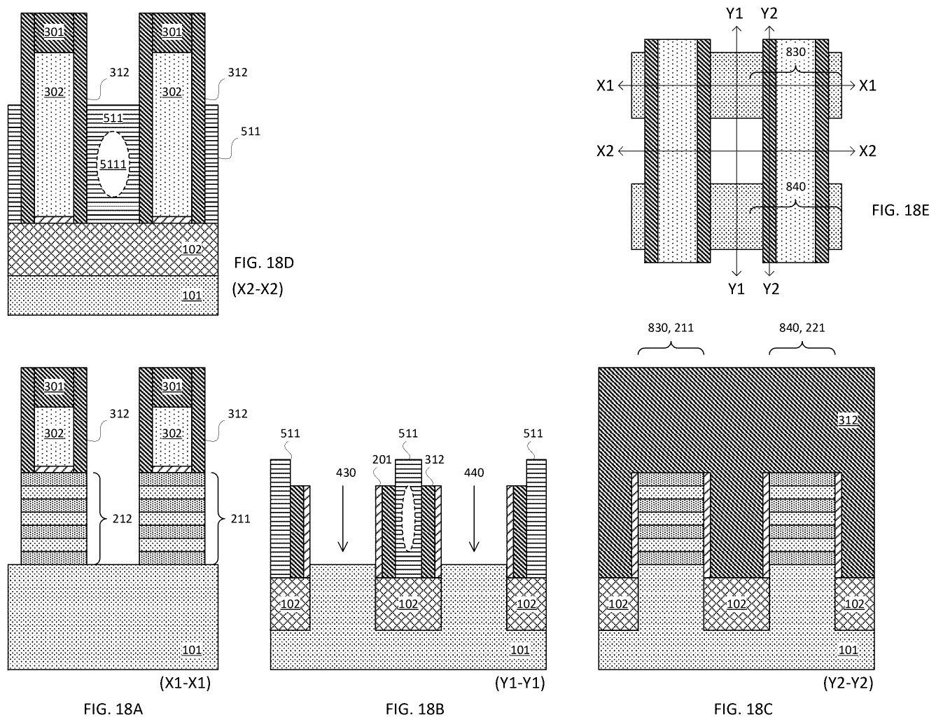

FIGS. 18A, 18B, 18C, and 18D are demonstrative illustrations of different cross-sectional views and FIG. 18E is a simplified top view of a semiconductor structure in a step of manufacturing thereof according to one embodiment of present invention. More specifically, following the step illustrated in FIGS. 17A, 17B, 17C, 17D, and 17E, embodiments of present invention provide recessing the first raw stack of nanosheets 210 and the second raw stack of nanosheets 220 that are exposed between the set of sacrificial gates 302 to create a plurality of sets of nanosheets. For example, a selective etch process may be applied to remove portions of the first raw stack of nanosheets 210 thereby creating a first set of nanosheets 211 and a third set of nanosheets 212. Similarly, the second raw stack of nanosheets 220 may be recessed to create several sets of nanosheets including a second set of nanosheets 221 and a fourth set of nanosheets.

The removal of the portions of the first and the second raw stack of nanosheets 210 and 220 may thus create a first opening 430 and a second opening 440 that are self-aligned with the isolation layer 511, the dielectric liner 201, and the sidewall spacers 312. In other words, with the dielectric liner 201 and sidewall spacers 312 staying next to the sidewalls of the isolation layer 511, the first and the second opening 430 and 440 may have a T-shaped cross-section, as is demonstratively illustrated in FIG. 18B, and a normal to the cross-section is in a length direction of the plurality of sets of nanosheets such as the first set of nanosheets 211. The length direction of the plurality of sets of nanosheets is a length direction of the set of sacrificial gates 302 and the metal gates to be formed later, which is a left-to-right direction in FIG. 18A or a direction going into or out of the paper in FIG. 18B. The T-shaped cross-section may have a first width at a top portion and a second width at a bottom portion with the first width being wider than the second width.

A lower portion of the T-shaped opening may be self-aligned with a ridged portion of the substrate 101. The ridged portion of the substrate 101 may be surrounded by the one or more STI structures 102. The first and the second opening 430 and 440 may expose end surfaces of the plurality of sets of nanosheets such as end surfaces of the first set of nanosheets 211 and the second set of nanosheets 221. The first and the second opening 430 and 440 may be used to form S/D regions of a first and a second nanosheet transistor 830 and 840 and the S/D regions may be isolated from each other by the isolation layer 511, as being described below in more details.

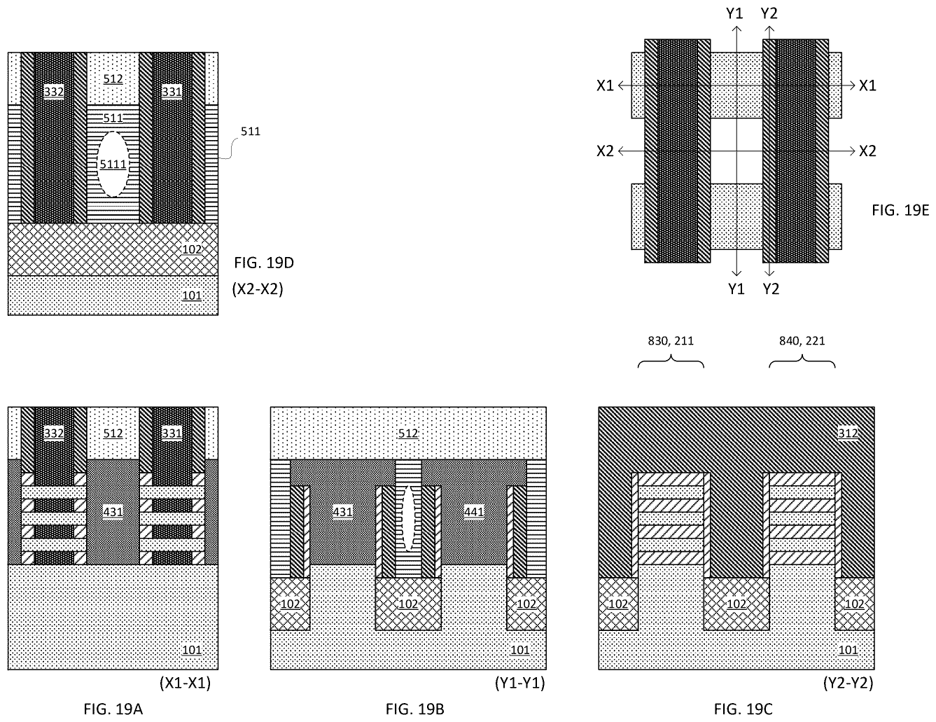

FIGS. 19A, 19B, 19C, and 19D are demonstrative illustrations of different cross-sectional views and FIG. 19E is a simplified top view of a semiconductor structure in a step of manufacturing thereof according to one embodiment of present invention. More specifically, following the step illustrated in FIGS. 18A, 18B, 18C, 18D, and 18E, embodiments of present invention provide creating indentations at the set of sacrificial sheets of the plurality of sets of nanosheets; forming inner spacers at the indentions; and epitaxially growing S/D regions, such as a first S/D region 431 and a second S/D region 441, at the longitudinal ends of the channel sheets of the plurality of sets of nanosheets. Unlike the first and the second S/D region 411 and 421 illustrated in FIG. 11B, the first and the second S/D region 431 and 441 may have a wider top portion, with a first width, and a narrower bottom portion, with a second width, to have a T-shaped cross-section with a normal to the cross-section in the length direction of the metal gates of the first and the second nanosheet transistor 830 and 840, as is demonstratively illustrated in FIG. 19B. The bottom portions of the first and the second S/D region 431 and 441 may be formed to be substantially aligned with the ridged portions of the substrate 101 and may have a substantially same width as a width of the first and the second set of nanosheets 211 and 221. In one embodiment, embodiments of present invention provide performing the above steps in a manner substantially similar to the steps described above with reference to FIGS. 9A, 9B, 9C, 9D, and 9E to FIGS. 11A, 11B, 11C, 11D, and 11E.

After forming the S/D regions, embodiments of present invention provide forming an ILD layer 512 on top of the first and the second S/D region 431 and 441 and on top of the isolation layer 511. The ILD layer 512 may be formed through a deposition process followed by a CMP process and may include or be made of, for example, SiOx, SiN, SiC, SiBCN, SiOC, SiOCN or other suitable low-k dielectric materials. Following the formation of the ILD layer 512, the gate masks 301 may be removed through a CMP process to expose the set of sacrificial gates 302, and a RMG process may be applied to replace the set of sacrificial gates 302 with a set of metal gates such as a first metal gate 331 and a second metal gate 332. In one embodiment, the first and the second metal gates 331 and 332 may be shared metal gates. For example, the first metal gate 331 may be a metal gate shared by the first nanosheet transistor 830 and the second nanosheet transistor 840.

The first and the second metal gate 331 and 332 may include, for example, a gate dielectric, one or more WFM layers, and one or more gate metals of conductive material such as, for example, Cu, Al, Ru, Co, and W. In one embodiment, the above steps may be made in a manner substantially similar to the steps described above with reference to FIGS. 12A, 12B, 12C, 12D, and 12E to FIGS. 13A, 13B, 13C, 13D, and 13E.

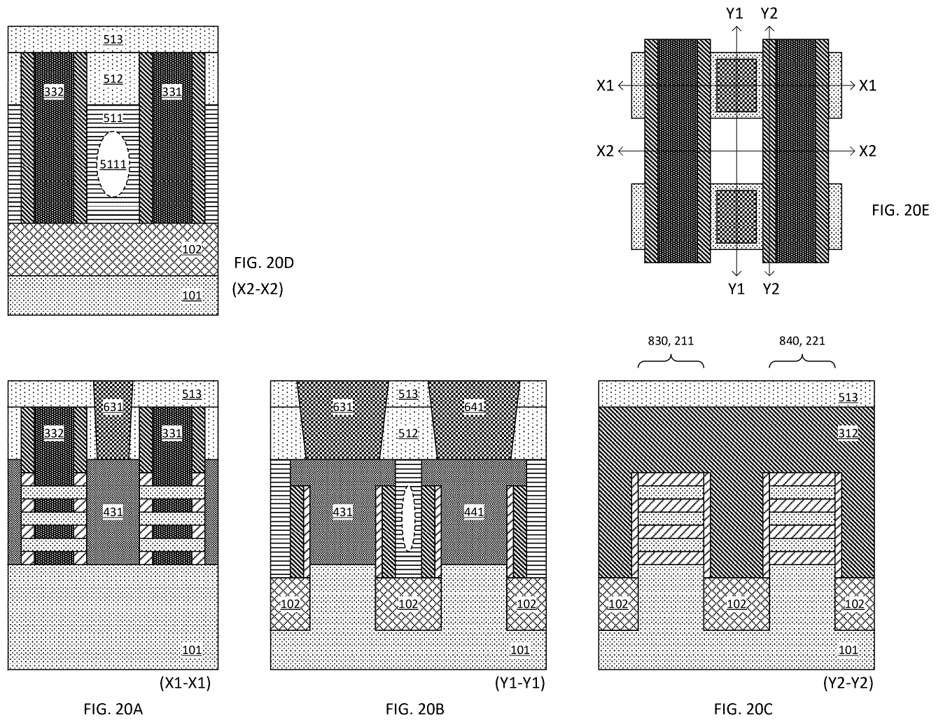

FIGS. 20A, 20B, 20C, and 20D are demonstrative illustrations of different cross-sectional views and FIG. 20E is a simplified top view of a semiconductor structure in a step of manufacturing thereof according to one embodiment of present invention. More specifically, following the step illustrated in FIGS. 19A, 19B, 19C, 19D, and 19E, embodiments of present invention provide forming an ILD layer 513 on top of the first and the second metal gate 331 and 332 and on top of the ILD layer 512. In one embodiment, the ILD layer 513 may include or be made of SiOx, SiN, SiC, SiBCN, SiOC, and SiOCN and may preferably be made of low-k dielectric materials. The ILD layer 513 may be substantially same as the ILD layer 512. one or more contacts may then be formed through the ILD layer 513 and/or the ILD layer 512 to contact the S/D regions and/or metal gates of the first and the second nanosheet transistor 830 and 840. For example, a first S/D contact 631 may be made to contact the first S/D region 431 and a second S/D contact 641 may be made to contact the second S/D region 441. Gate contacts may be made to contact the first metal gate 331 and/or the second metal gate 332 as well.

FIGS. 21A, 21B, 21C, and 21D are demonstrative illustrations of different cross-sectional views and FIG. 21E is a simplified top view of a semiconductor structure 30 in a step of manufacturing thereof according to yet another embodiment of present invention. Here, it is to be noted that FIG. 21C illustrates a cross-sectional view of the semiconductor structure 30 with the cross-section made along a line Y3-Y3 as illustrated in FIG. 21E. In other words, the cross-sectional view in FIG. 21C is made across the gate in a direction along the width of the gate.

More specifically, following the step illustrated in FIGS. 20A, 20B, 20C, 20D, and 20E or alternately, although not shown here, following the step illustrated in FIGS. 14A, 14B, 14C, 14D, and 14E, embodiments of present invention provide performing a gate-cut that cuts the first metal gate 331 into a metal gate 3311 of a first nanosheet transistor 850 and a metal gate 3312 of a second nanosheet transistor 860, and filling the gate-cut with a dielectric material to form a gate-cut structure 391 that separates and isolates the metal gate 3311 from the metal gate 3312. The gate-cut structure 391 may be made sufficiently deep to at least reach one of the one or more STI structures 102.

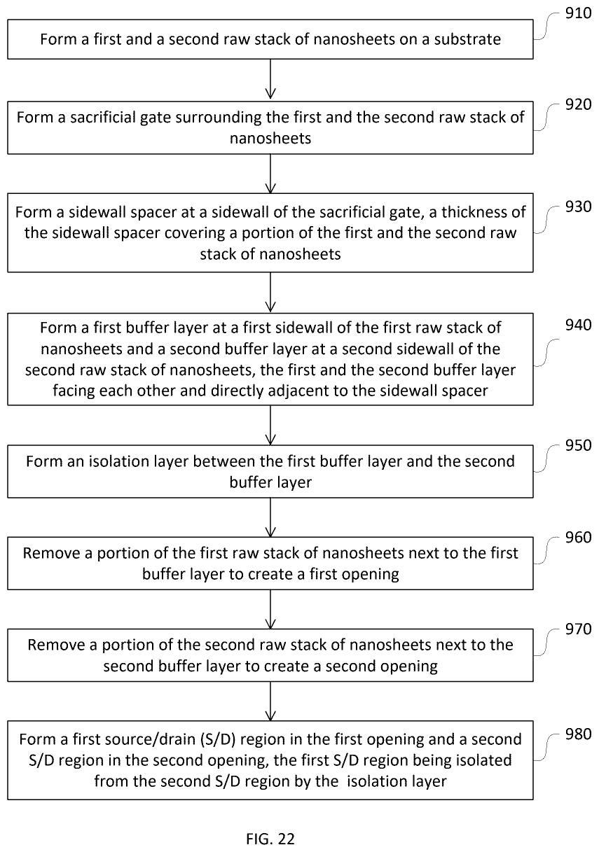

FIG. 22 is a demonstrative illustration of a flow-chart of a method of manufacturing a semiconductor structure according to embodiments of present invention. The method includes (910) forming a first and a second raw stack of nanosheets on a substrate; (920) forming a sacrificial gate surrounding the first and the second raw stack of nanosheets; (930) forming a sidewall spacer at a sidewall of the sacrificial gate, a thickness of the sidewall spacer covering a portion of the first and the second raw stack of nanosheets; (940) forming a first buffer layer at a first sidewall of the first raw stack of nanosheets and a second buffer layer at a second sidewall of the second raw stack of nanosheets, the first and the second buffer layer facing each other and directly adjacent to the sidewall spacer; (950) forming an isolation layer between the first buffer layer and the second buffer layer; (960) removing a portion of the first raw stack of nanosheets next to the first buffer layer to create a first opening; (970) removing a portion of the second raw stack of nanosheets next to the second buffer layer to create a second opening; and (980) forming a first source/drain (S/D) region in the first opening and a second S/D region in the second opening, the first S/D region being isolated from the second S/D region by the isolation layer.

It is to be understood that the exemplary methods discussed herein may be readily incorporated with other semiconductor processing flows, semiconductor devices, and integrated circuits with various analog and digital circuitry or mixed-signal circuitry. In particular, integrated circuit dies can be fabricated with various devices such as field-effect transistors, bipolar transistors, metal-oxide-semiconductor transistors, diodes, capacitors, inductors, etc. An integrated circuit in accordance with the present invention can be employed in applications, hardware, and/or electronic systems. Suitable hardware and systems for implementing the invention may include, but are not limited to, personal computers, communication networks, electronic commerce systems, portable communications devices (e.g., cell phones), solid-state media storage devices, functional circuitry, etc. Systems and hardware incorporating such integrated circuits are considered part of the embodiments described herein. Given the teachings of the invention provided herein, one of ordinary skill in the art will be able to contemplate other implementations and applications of the techniques of the invention.

Accordingly, at least portions of one or more of the semiconductor structures described herein may be implemented in integrated circuits. The resulting integrated circuit chips may be distributed by the fabricator in raw wafer form (that is, as a single wafer that has multiple unpackaged chips), as a bare die, or in a packaged form. In the latter case the chip may be mounted in a single chip package (such as a plastic carrier, with leads that are affixed to a motherboard or other high-level carrier) or in a multichip package (such as a ceramic carrier that has surface interconnections and/or buried interconnections). In any case the chip may then be integrated with other chips, discrete circuit elements, and/or other signal processing devices as part of either an intermediate product, such as a motherboard, or an end product. The end product may be any product that includes integrated circuit chips, ranging from toys and other low-end applications to advanced computer products having a display, a keyboard or other input device, and a central processor.

The descriptions of various embodiments of present invention have been presented for the purposes of illustration and they are not intended to be exhaustive and present invention are not limited to the embodiments disclosed. The terminology used herein was chosen to best explain the principles of the embodiments, practical application or technical improvement over technologies found in the marketplace, and to enable others of ordinary skill in the art to understand the embodiments disclosed herein. Many modifications, substitutions, changes, and equivalents will now occur to those of ordinary skill in the art. Such changes, modification, and/or alternative embodiments may be made without departing from the spirit of present invention and are hereby all contemplated and considered within the scope of present invention. It is, therefore, to be understood that the appended claims are intended to cover all such modifications and changes as fall within the spirit of the invention.

What is claimed is:

1. A semiconductor structure comprising:
a first and a second set of channel sheets on top of a semiconductor substrate;
a metal gate surrounding the first and the second set of channel sheets;
a sidewall spacer next to a sidewall of the metal gate, a thickness of the sidewall spacer covering the first and the second set of channel sheets at a top and sidewalls thereof;
a first and a second source/drain (S/D) region at an end surface of the first and the second set of channel sheets respectively; and
an isolation layer between a first sidewall of the first S/D region and a second sidewall of the second S/D region,
wherein the isolation layer is directly adjacent to the sidewall spacer.

2. The semiconductor structure of claim 1, wherein the first and the second S/D region have a substantially rectangular shape of cross-section with a normal to the cross-section in a length direction of the metal gate.

3. The semiconductor structure of claim 2, wherein a width of the first S/D region is wider than a width of the first set of channel sheets, and a width of the second S/D region is wider than a width of the second set of channel sheets.

4. The semiconductor structure of claim 1, wherein the first and the second S/D region have a T-shaped cross-section with a normal to the cross-section in a length direction of the metal gate, the cross-section having a first width at a top portion and a second width at a bottom portion, the first width being wider than the second width.

5. The semiconductor structure of claim 4, wherein the second width at the bottom portion of the first and the second S/D region is substantially same as a width of the first and the second set of channel sheets.

6. The semiconductor structure of claim 1, wherein the isolation layer comprises one or more air gaps.

7. A method comprising:
forming a first and a second raw stack of nanosheets on a substrate;
forming a sacrificial gate surrounding the first and the second raw stack of nanosheets;
forming a sidewall spacer at a sidewall of the sacrificial gate, a thickness of the sidewall spacer covering a portion of the first and the second raw stack of nanosheets;
forming a first buffer layer at a first sidewall of the first raw stack of nanosheets and a second buffer layer at a second sidewall of the second raw stack of nanosheets, the first and the second buffer layer facing each other and directly adjacent to the sidewall spacer;
forming an isolation layer between the first buffer layer and the second buffer layer;
removing a portion of the first raw stack of nanosheets next to the first buffer layer to create a first opening;
removing a portion of the second raw stack of nanosheets next to the second buffer layer to create a second opening; and
forming a first source/drain (S/D) region in the first opening and a second S/D region in the second opening, the first S/D region being isolated from the second S/D region by the isolation layer.

8. The method of claim 7, wherein removing the first raw stack of nanosheets next to the first buffer layer creates a first set of nanosheets surrounded by the sacrificial gate, the first set of nanosheets includes a set of channel sheets and a set of sacrificial sheets, further comprising replacing the sacrificial gate and the set of sacrificial sheets with a metal gate to surround the set of channel sheets.

9. The method of claim 7, wherein forming the sidewall spacer at the sidewall of the sacrificial gate further comprises forming the sidewall spacer at the first sidewall of the first raw stack of nanosheets and at the second sidewall of the second raw stack of nanosheets.

10. The method of claim 9, further comprising, before forming the first and the second buffer layer, removing an upper portion of the sidewall spacer at the first sidewall of the first raw stack of nanosheets and an upper portion of the sidewall spacer at the second sidewall of the second raw stack of nanosheets.

11. The method of claim 10, wherein the first and the second opening, and the first and the second S/D region formed therein, have a T-shaped cross-section with a first width at a top and a second width at a bottom, the first width being wider than the second width.

12. The method of claim 11, wherein forming the isolation layer further comprises forming one or more air gaps in the isolation layer.

13. The method of claim 9, further comprising, before forming the first and the second buffer layer, removing the sidewall spacer at the first sidewall of the first raw stack of nanosheets and at the second sidewall of the second raw stack of nanosheets.

14. The method of claim 13, wherein the first and the second opening, and the first and the second S/D region formed therein, have a substantially rectangular shape of cross-section.

15. A semiconductor structure comprising:
a first and a second nanosheet transistor, the first and the second nanosheet transistor comprise:
a first and a second metal gate respectively surrounding a first and a second set of channel sheets respectively, the first and the second metal gate being isolated by a gate-cut structure;
a sidewall spacer next to a sidewall of the first and the second metal gate;
a first and a second S/D region respectively; and
an isolation layer between the first and the second S/D region,
wherein the isolation layer is horizontally adjacent to the sidewall spacer.

16. The semiconductor structure of claim 15, wherein the first and the second S/D region have a substantially rectangular shape of cross-section that faces a length direction of the first and the second metal gate.

17. The semiconductor structure of claim 16, wherein a width of the first S/D region is wider than a width of the first set of channel sheets.

18. The semiconductor structure of claim 15, wherein the first and the second S/D region have a T-shaped cross-section that faces a length direction of the first and the second metal gate, the T-shaped cross section has a first width at a top portion and a second width at a bottom portion, the first width being wider than the second width.

19. The semiconductor structure of claim 18, wherein the second width at the bottom portion of the first and the second S/D region is substantially same as a width of the first and the second set of channel sheets.

20. The semiconductor structure of claim 15, wherein the isolation layer comprises one or more air gaps.
